(19) United States
(12) Patent Application Publication
(10) Pub. No.: US 2025/0338615 A1
(43) Pub. Date: Oct. 30, 2025

(54) STACKED TRANSISTORS WITH DISCONTINUOUS HIGH-K ON VERTICAL GATE SPACERS

(71) Applicant: International Business Machines Corporation, Armonk, NY (US)

(72) Inventors: Abir Shadman, Albany, NY (US); Shay Reboh, Guilderland, NY (US); Debarghya Sarkar, Latham, NY (US); Junli Wang, Slingerlands, NY (US); Paul Charles Jamison, Averill Park, NY (US); Takashi Ando, Eastchester, NY (US)

(21) Appl. No.: 18/648,602

(22) Filed: Apr. 29, 2024

(51) Int. Cl. H01L 27/092; H01L 21/822; H01L 21/8238; H01L 27/06; H01L 29/06; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 64/021; H10D 84/0184; H10D 84/038; H10D 88/00; H10D 88/01

(57) ABSTRACT

Embodiments of the present disclosure include stacked complementary transistors having a high-k material, a common work function metal, and a gate conductor metal. A vertically stacked sidewall is adjacent to the gate conductor metal, the vertically stacked sidewall including a first spacer and a second spacer, the second spacer being stacked on the first spacer. The high-k material is on an inner sidewall of the second spacer.

### BACKGROUND

The present invention generally relates to fabrication methods and resulting structures for stacked field-effect transistors (SFETs) with a common work function metal and selective oxygenation through discontinuous high-k material on inner sidewalls facilitated by vertical gate spacer stacking.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

One or more embodiments of the present invention are directed to stacked field-effect transistors (SFETs) with a common work function metal and selective oxygenation through discontinuous high-k material on inner sidewalls facilitated by vertical gate spacer stacking. A non-limiting method includes forming stacked complementary transistors comprising a high-k material, a common work function metal, and a gate conductor metal. The method includes providing a vertically stacked sidewall adjacent to the gate conductor metal, the vertically stacked sidewall comprising a first spacer and a second spacer, the second spacer being stacked on the first spacer. The high-k material is on an inner sidewall of the second spacer.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, and 1C respectively depict a top view and cross-sectional views of a portion of an integrated circuit (IC) according to one or more embodiments of the invention;

FIGS. 2A, 2B, 2C, and 2D depict cross-sectional views of a portion of an IC after fabrication operations according to one or more embodiments;

FIGS. 3A, 3B, 3C, and 3D depict cross-sectional views of a portion of an IC after fabrication operations according to one or more embodiments;

FIGS. 4A, 4B, 4C, and 4D depict cross-sectional views of a portion of an IC after fabrication operations according to one or more embodiments;

FIG. 5 depicts a cross-sectional view of a portion of an IC after fabrication operations according to one or more embodiments;

FIG. 6 depicts a cross-sectional view of a portion of an IC after fabrication operations according to one or more embodiments;

FIG. 7 depicts a cross-sectional view of a portion of an IC after fabrication operations according to one or more embodiments;

FIG. 8 depicts a cross-sectional view of a portion of an IC after fabrication operations according to one or more embodiments; and

FIG. 9 depicts a flowchart of a method of forming a semiconductor structure according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field-effect transistors (NFET) and p-type field-effect transistors (PFET) are two types of complementary MOSFETs. The NFET includes n-doped source and drain junctions and uses electrons as the current carriers. The PFET includes p-doped source and drain junctions and uses holes as the current carriers.

One or more embodiments of the present invention relate to stacked field-effect transistors (SFETs) with a common work function metal and selective oxygenation through discontinuous high-k material on inner sidewalls facilitated by vertical gate spacer stacking.

Stacked transistors have a top transistor stacked on a bottom transistor. Forming a replacement metal gate module for stacked nanosheet technology may be challenging in terms of process control. This is because the replacement metal gate processes for complementary transistors requires removing the gate metal from the top stack, which was deposited during the replacement metal gate formation for the bottom stack, and replacing the removed gate metal with work function metal suitable for the top stack. Removing the top replacement metal gate also affects the bottom transistor gate stack because etching is mostly a wet chemical process. The wet barrier recess has a comparatively smaller window, for example, up to the thickness of middle dielectric isolation layer, thereby placing a strong requirement for a thicker middle dielectric isolation layer.

One or more embodiments provide an advantage by using different gate spacers in the top and bottom stacks, where there is a discontinuous high-k material on the inner spacer sidewall. The use of different gate spacers in which one has a high-k material on the inner spacer sidewall creates the desired/matched work function for both the top and bottom transistors; this can be accomplished by effective work function (EWF) control through top-down oxygenation in the top transistor (e.g. PFET) while the top-down oxygenation effect is null for bottom transistor (e.g., NFET) because there is no high-k sidewall there. The process uses a selective etch/recess process of the side gate spacers in the source/drain module, before the replacement metal gate module, but the recess window is larger (two Tsus thickness+MDI) than the process of record (POR) organic dielectric layer (ODL) recess in replacement metal gate, Tsus is the nanosheet spacing. Typically, the POR ODL recess scheme has a window of up to MDI thickness; however, in embodiments, the gate spacer recess window is MDI plus two Tsus thickness (each Tsus is below and above the MDI).

In one or more embodiments, a vertically stacked gate spacer includes two (or more) gate spacers/materials vertically stacked, such as a bottom gate spacer and top gate spacer. A high-k liner is on the inner sidewall of only one gate spacer material of the vertically stacked gate spacers. The stacked transistors have the same work function metal (WFM) for both the bottom transistor (e.g., NFET) and the top transistor (e.g., PFET).

The bottom gate spacer and the middle dielectric isolation layer are of the same material that is different from material of the top gate spacer. The high-k liner is on the sidewall of only the spacer material on the PFET side, for example, adjacent to the PFET. The oxygen vacancy is lower in high-k material surrounding the nanosheets in top transistor (e.g., PFET) than the high-k material surrounding the bottom transistor (e.g., NFET).

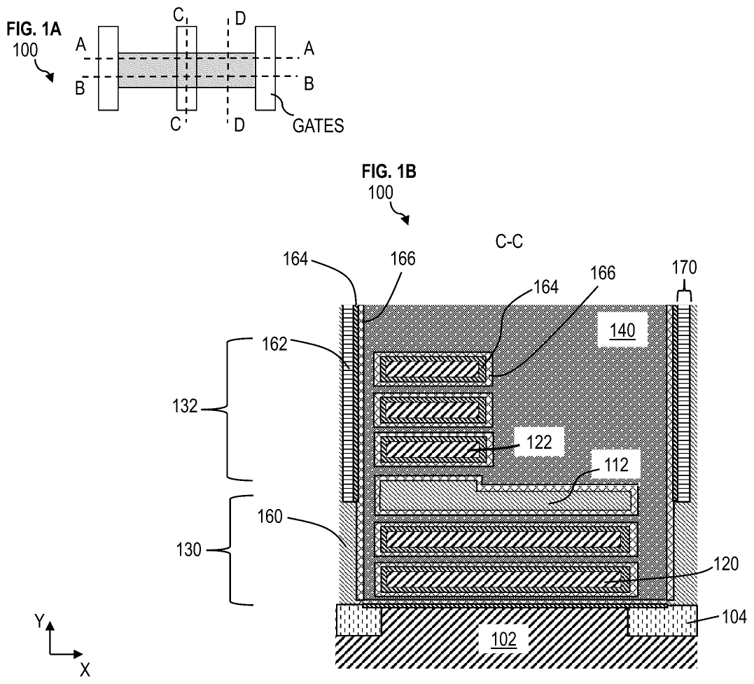

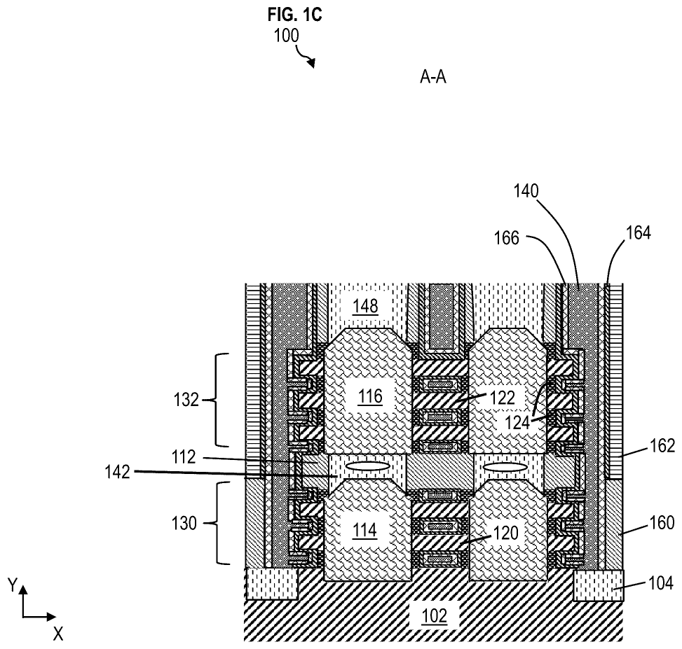

Turning now to a more detailed description of aspects of the present disclosure, FIG. 1A depicts a top view of a simplified illustration of a portion of an integrated circuit (IC) 100, FIG. 1B depicts a cross-sectional view taken along C-C of the IC 100, and FIG. 1C depicts a cross-sectional view taken along A-A of the IC 100. FIG. 1A illustrates dashed lines representing various cross-sectional views that will be shown herein. For ease of understanding, some layers may be omitted from the top view so as not to obscure the figure and to view layers underneath. As such, the top view is intended to provide a simplified illustration and a general orientation of a portion of the IC. Standard semiconductor fabrication techniques can be utilized to fabricate the IC as understood by one of ordinary skill in the art. Any suitable lithography processes including deposition techniques and etching techniques can be utilized herein. The IC 100 includes stacked transistors having a bottom transistor 130 and a top transistor 132, where the top transistor 132 is stacked on the bottom transistor 130. The bottom transistor 130 and the top transistor 132 are illustrated as nanosheet transistors having gate material wrapping around their respective nanosheets 120 and 122, which serve as the channel regions. The bottom transistor 130 includes nanosheets 120, and the top transistor includes nanosheets 122. The nanosheets 120 and 122 are made of semiconductor materials. Example materials of the nanosheets 120 and 122 can include pure silicon. Other example materials of nanosheets 120 and 122 can include silicon, silicon germanium (SiGe), III-V semiconductors, etc., and dopants can be added as desired to enhance carrier properties. Although nanosheet transistors are illustrated for explanation purposes, one or more embodiments can have other types of stacked transistors.

A high-k dielectric material 164 surrounds the nanosheets 120 and 122 of the bottom and top transistors 130 and 132. The high-k dielectric material 164 may include hafnium oxide or other suitable materials. As formed on top of the high-k dielectric material 164, the (same) work function metal 166 surrounds the nanosheets 120 and 122 in both the bottom and top transistors 130 and 132. A gate contact 140 is formed around the nanosheets 120 and 122, the high-k dielectric material 164, and the work function metal 166. A vertically stacked gate sidewall 170 includes a top gate spacer 162 stacked on a bottom gate spacer 160, which are formed of material with differing amounts of hydrogen (H). A liner of the high-k dielectric material 164 is formed on the inner sidewall of the top gate spacer 162 but is not formed on the inner sidewall of the bottom gate spacer 160. The liner of the high-k dielectric material 164 is excluded from the inner sidewall of the bottom gate spacer 160 because of the hydrogen present in the material of the bottom gate spacer 160. Example materials of the bottom gate spacer 160 can include SiBCN with hydrogen (H) terminated on the surface or SiN with a high hydrogen concentration. In one or more embodiments, SiBCN can be functionalized with hydrogen to terminate on the outer surface. SiBCN can be functionalized by exposing the film to hydrogen-containing plasma during the deposition process to terminate on the outer surface with hydrogen. In one or more embodiments, the bottom gate spacer 160 can be doped with hydrogen. In one or more embodiments, the SiN can be doped with hydrogen. The hydrogen blocks or prevents the high-k dielectric material 164 from forming a liner on the bottom gate spacer 160. Other example materials of the bottom gate spacer 160 may include silicon carbide (SiC), silicon carbon oxygen (SiCO), SiOCN, etc., each terminated with hydrogen and/or doped with hydrogen, such that the high-k dielectric material 164 is not formed thereon.

In one or more embodiments, the materials of the top gate spacer 162 exclude hydrogen. Example materials of the top gate spacer 162 can include SiBCN, SiN, etc., which do not terminate with hydrogen and/or do not include hydrogen, such that the high-k dielectric material 164 can be formed on the inner sidewall. Oxygenation is performed to cause oxygen atoms from the liner of high-k dielectric material 164 on the top gate spacer 162 to be transferred to the high-k dielectric material 164 surrounding the nanosheets 122 of the top transistor 132, while not being transferred to high-k dielectric material 164 surrounding the nanosheets 122 of the bottom transistor 130. In one or more embodiments, oxygenation annealing can be at about 400 Celsius (C) at about 10 torr (T) for about 10 minutes (mins). As such, the oxygenation results in the high-k dielectric material 164 surrounding the nanosheets 122 of the top transistor 132 having a lower oxygen vacancy than the higher oxygen vacancy of the high-k dielectric material 164 surrounding the nanosheets 122 of the bottom transistor 130. The middle dielectric isolation layer 112 serves as a boundary layer to prevent the oxygen transferred from the liner of high-k dielectric material 164 on the top gate spacer 162 from being received by the high-k dielectric material 164 surrounding the nanosheets 120 in the bottom transistor 130. The liner of high-k dielectric material 164 on the top gate spacer 162 is above the bottom surface of the middle dielectric isolation layer 112 in the y-axis.

Example materials of the gate contact can include tungsten (W), cobalt (Co), gold (Au), copper (Cu), nickel (Ni), cobalt (Co), etc.

As best seen in FIG. 1B, the bottom transistor 130 has bottom source/drain regions 114, while the top transistor 132 has top source/drain regions 116. The source/drain regions can be n-type and p-type in accordance with NFET and PFET devices. A self-aligned cap 142 is formed above the bottom source/drain regions 114, and a self-aligned cap 148 is formed above the top source/drain regions 116. Inner spacers 124 are formed between nanosheets 120 and 122. The inner spacers 124 can be formed of low-k dielectric material, ultra-low-k dielectric material, etc. Shallow trench isolation regions 104 are formed in the substrate 102.

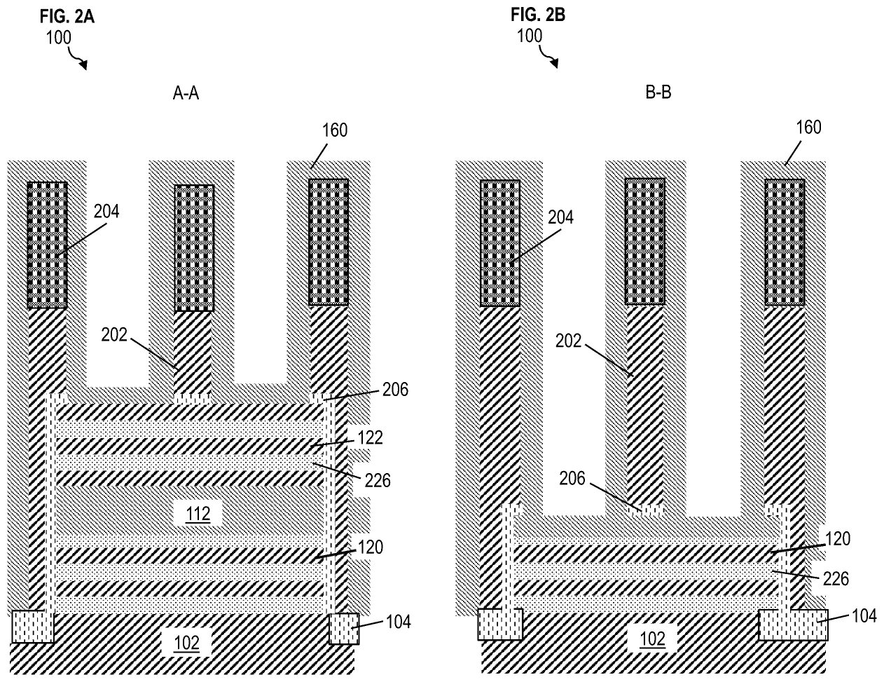

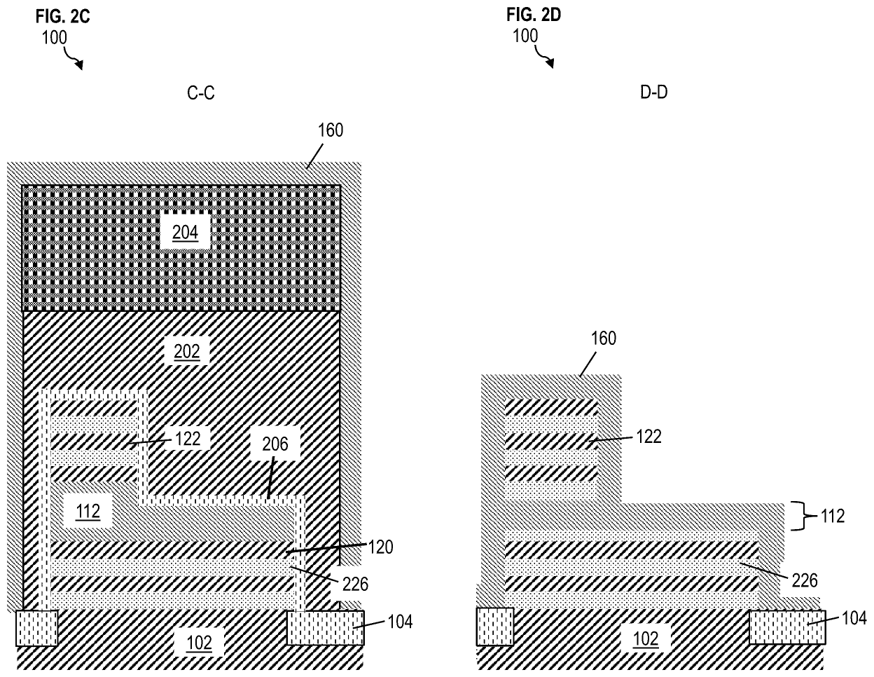

Now turning to the fabrication process, FIGS. 2A, 2B, 2C, and 2D depict cross-sectional views respectively taken along lines A-A, B-B, C-C, and D-D of the IC 100. FIGS. 2A, 2B, 2C, and 2D depict the IC 100 having a wafer where several fabrication processes have been performed. Alternating layers are formed on the substrate 102, such that sacrificial layers 226 are formed between the nanosheets 120 and 122. Shallow trench isolation regions 104 are formed in the substrate 102. Fins 202 are formed, and a hard mask layer 204 is formed on the fins 202. A portion of the nanosheets 122 can be patterned as depicted in FIG. 2D. Sacrificial layer 206 is formed around the nanosheets 120 and 122. Gate spacer material of the bottom gate spacer 160 is formed on the fins 202, which is also utilized to form the middle dielectric isolation layer 112.

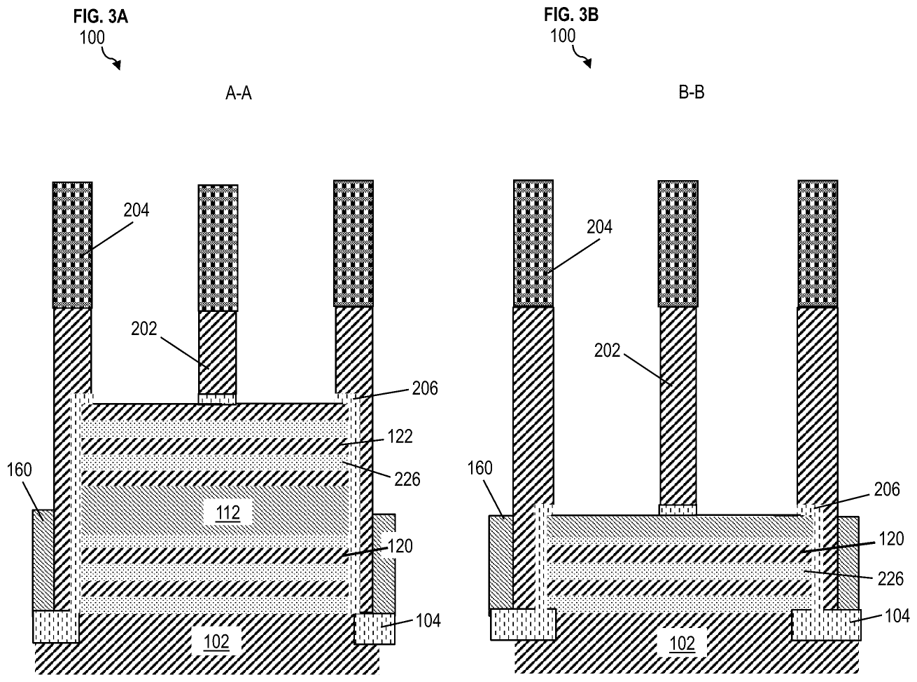

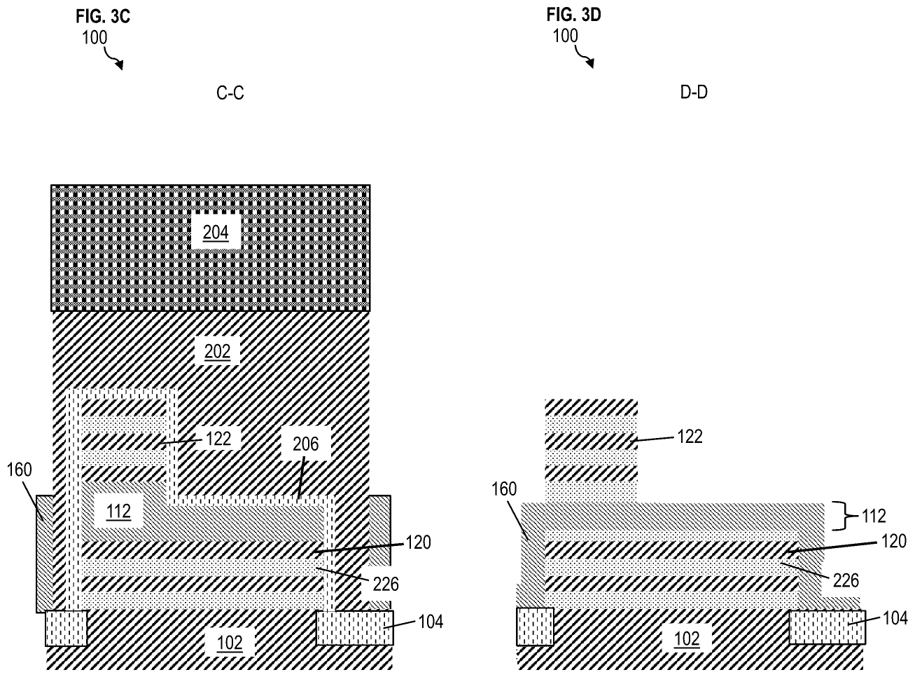

FIGS. 3A, 3B, 3C, and 3D depict cross-sectional views respectively taken along lines A-A, B-B, C-C, and D-D of the IC 100 after etching. Etching is performed to pull back the gate spacer material of the bottom gate spacer 160 without going below the middle dielectric isolation layer 112, in one or more embodiments. In one or more embodiments, the gate spacer material of the bottom gate spacer 160 is recessed within a window having a range from the end or bottom surface of the last nanosheet 122 in the top transistor 132 to the start of the top nanosheet 120 in the bottom transistor 130. Also, etching can be performed to remove portions of sacrificial layer 206.

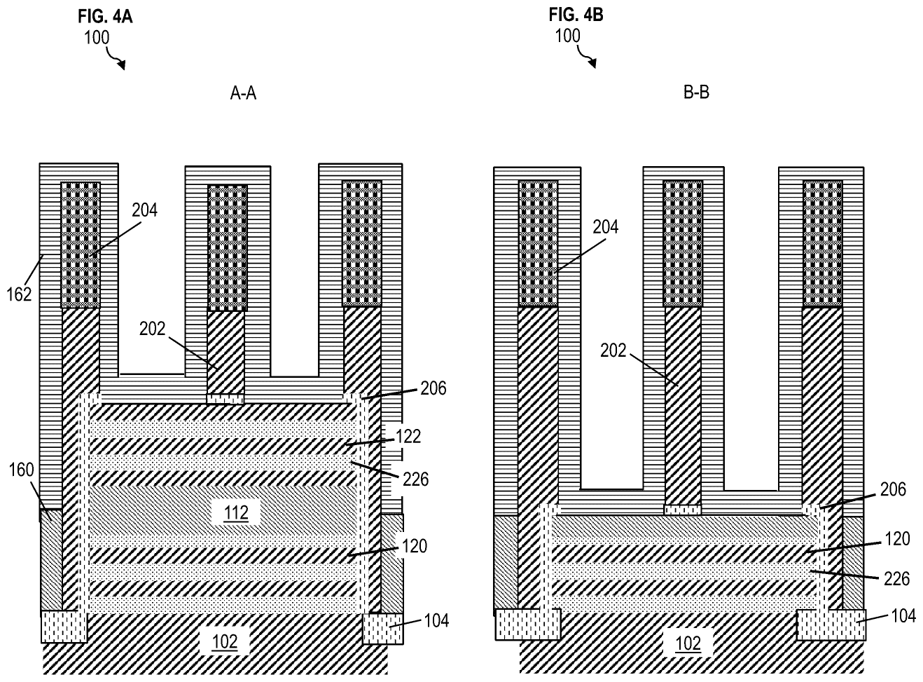

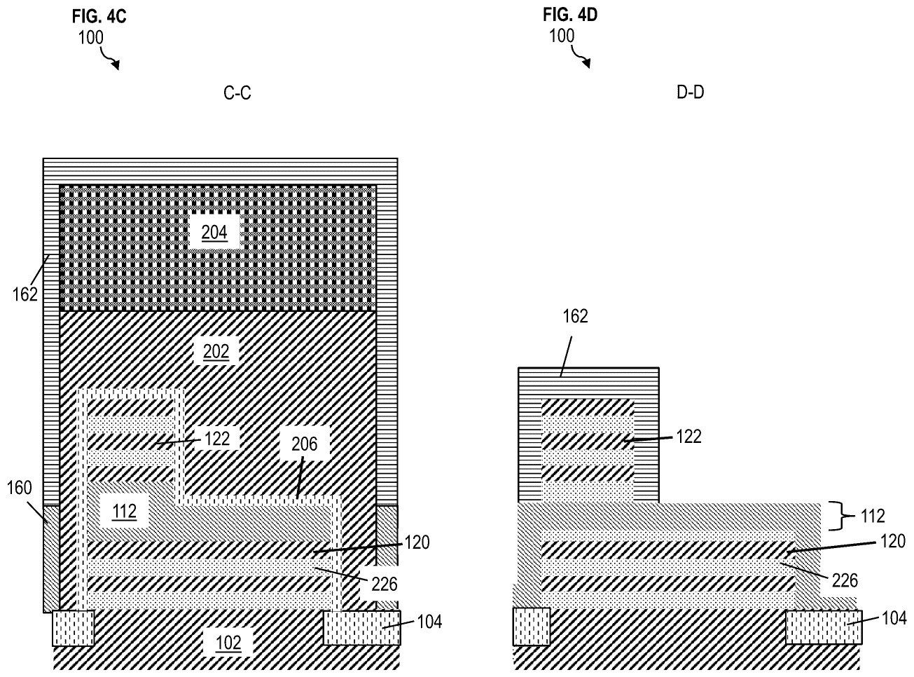

FIGS. 4A, 4B, 4C, and 4D depict cross-sectional views respectively taken along lines A-A, B-B, C-C, and D-D of the IC 100 after depositing the top spacer. Deposition is performed such that gate spacer material of the top gate spacer 162 is formed on top of the bottom gate spacer 160.

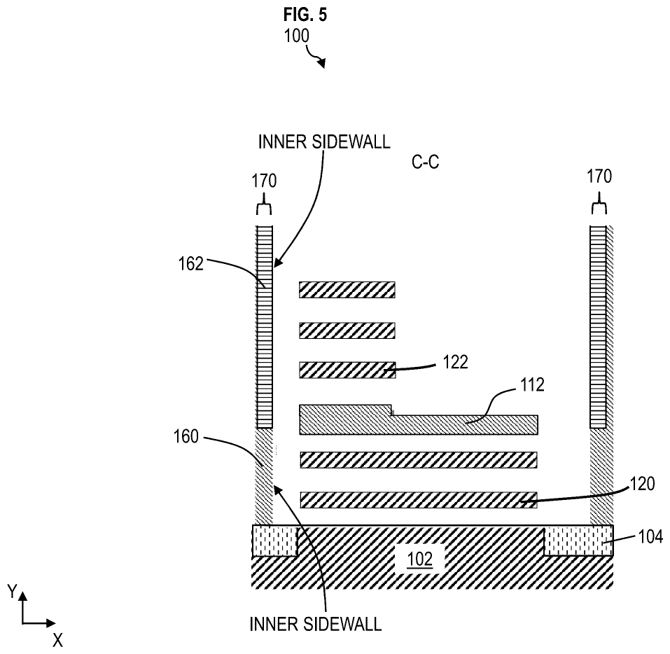

FIG. 5 depicts a cross-sectional view taken along line C-C of the IC 100 following the fabrication process of record. The fabrication process of record is known to one of ordinary skill in the art. Lithography is performed to remove open gate space material of the top gate spacer 162, form dummy gate, form source/drain regions 114 and 116, form the inner spacers 124, remove hard mask layer 204, etch fins, remove dummy gate, and release the nanosheets 120 and 122 by removing the sacrificial layers 206 and 226. Attention is directed to various novel features more clearly seen in view C-C. As seen in FIG. 5, the vertically stacked gate sidewalls 170 include the top gate spacer 162 stacked on the bottom gate spacer 160. At this stage, the inner sidewalls of the top gate spacer 162 and the bottom gate spacer 160 are free of material in FIG. 5.

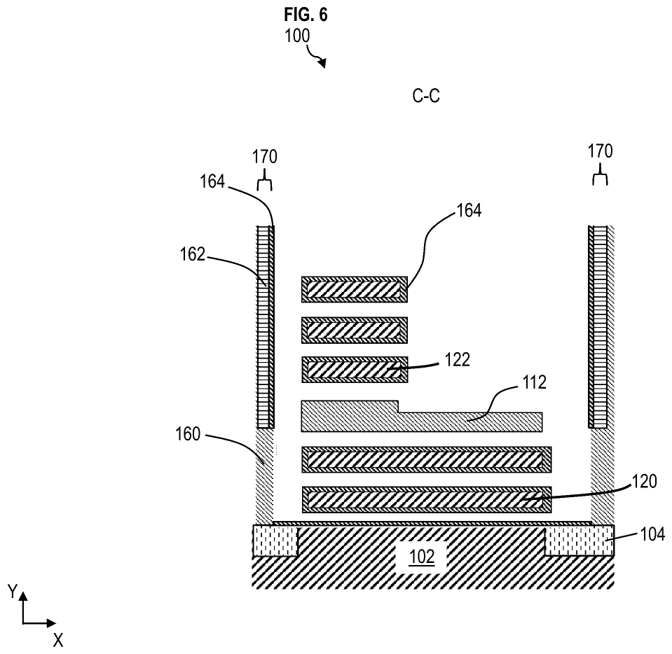

FIG. 6 depicts a cross-sectional view taken along line C-C of the IC 100 after high-k dielectric material deposition. As part of the replacement metal gate process, the high-k dielectric material 164 is formed around the nanosheets 120 and 122, and additionally, the high-k dielectric material 164 is formed as liner on the inner sidewalls of the top gate spacer 162 of the vertically stacked gate sidewalls 170. The high-k dielectric material 164 is not formed on the bottom gate spacer 160 because the high-k dielectric material 164 does not nucleate on the hydrogen-terminated surface of the bottom gate spacer 160.

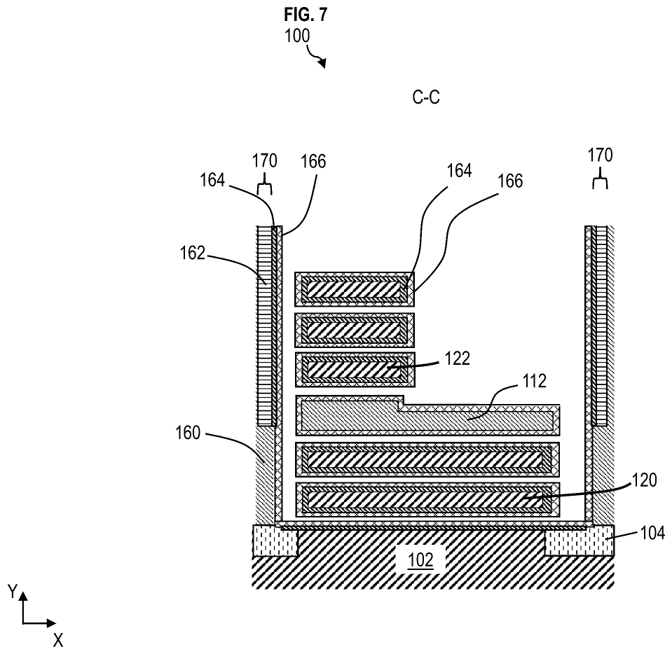

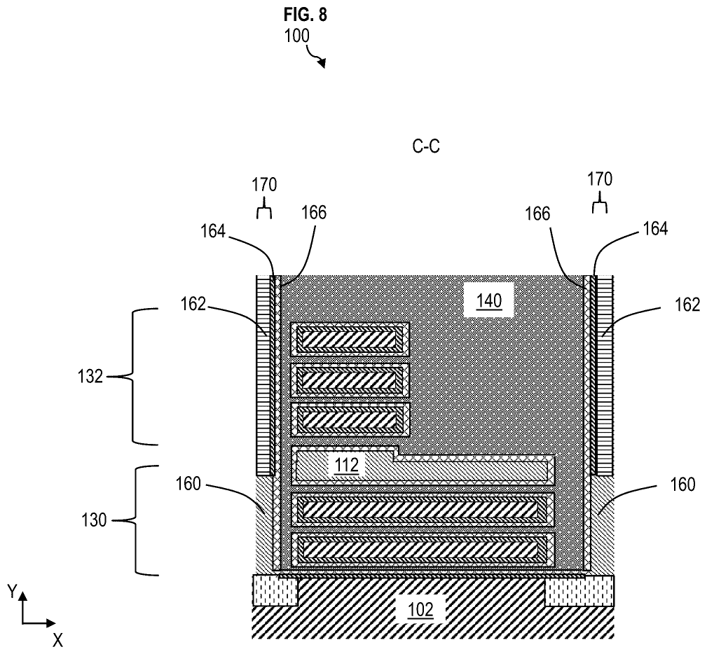

FIG. 7 depicts a cross-sectional view taken along line C-C of the IC 100 after work function metal deposition. The work function metal 166 is formed around the nanosheets 120 and 122 (e.g., around the high-k dielectric material 164 surrounding nanosheets 120 and 122) and is formed on the inner sidewalls of both the top gate spacer 162 and the bottom gate spacer 160 in the vertically stacked gate sidewalls 170. The work function metal 166 can be an n-type work function metal, such as for, example titanium nitride (TiN) or other suitable n-type work function materials. In a typical scenario, the n-type work function metal would need to be removed for a PFET device such as, for example, the top transistor 132, or another layer of work function metal may need to be deposited on the PFET device but not the NFET device. However, the present disclosure provides a novel technique of effective work function (EWF) control through top-down oxygenation in the top transistor (e.g. PFET) while the top-down oxygenation effect is null for bottom transistor (e.g., NFET) as discussed further in FIG. 8.

FIG. 8 depicts a cross-sectional view taken along line C-C of the IC 100 after gate conductor deposition. Oxygenation is performed to transfer oxygen atoms from the liner of high-k dielectric material 164 on the inner sidewalls of the top gate spacer 162 to the high-k dielectric material 164 surrounding the (top) nanosheets 122 of top transistor 132, but not the bottom transistor 130. This is because the liner of high-k dielectric material 164 on the inner sidewalls of the top gate spacer 162 is present above the bottom (surface) of the middle dielectric isolation layer 112 in the y-axis, thereby allowing oxygen atoms to be transferred from the liner of high-k dielectric material 164 on the inner sidewalls of the top gate spacer 162 to the high-k dielectric material 164 surrounding the (top) nanosheets 122 of top transistor 132 during the anneal oxygen process. In contrast, there is no liner of high-k dielectric material 164 on the inner sidewalls of the bottom gate spacer 160, and thus no oxygen is transferred to the high-k dielectric material 164 surrounding the bottom transistor 130. In one or more embodiments, oxygenation annealing can be at about 400 C at about 10 T for about 10 mins. The oxygenation results in a voltage threshold shift for the top transistor 132 (e.g., PFET). The metal of the gate contact 140 is formed around the nanosheets 122 in the top transistor 132 and the nanosheets 120 in the bottom transistor 130.

Although the liner of high-k dielectric material 164 is shown on the top gate spacer 162, it should be appreciated that materials can be reversed, and embodiments apply when the bottom transistor 130 is desired to have a threshold voltage shift. For example, the PFET could be the bottom transistor and the NFET could be the top transistor. Accordingly, the material of the bottom gate spacer and top gate spacer are interchanged, such that the liner of high-k dielectric material 164 is on the bottom gate spacer in one or more embodiments. Accordingly, the oxygenation causes the high-k dielectric material 164 surrounding the bottom transistor to receive the transfer of oxygen instead of the top transistor in this example scenario.

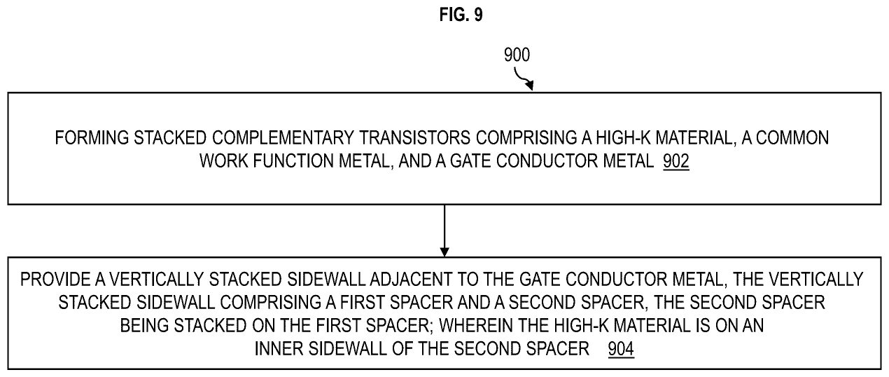

FIG. 9 is a flowchart of a method 900 of forming stacked field-effect transistors (SFETs) with a common work function metal and performing selective oxygenation through discontinuous high-k material on inner sidewalls facilitated by vertical gate spacer stacking according to one or more embodiments. Reference can be made to any of the figures discussed herein.

At block 902, the method 900 includes forming stacked complementary transistors (e.g., bottom transistor 130 and top transistor 132) including a high-k material (e.g., high-k dielectric material 164), a common work function metal 166, and a gate conductor metal (e.g., gate contact 140).

At block 904, the method 900 includes providing a vertically stacked sidewall (e.g., vertically stacked gate sidewalls 170) adjacent to the gate conductor metal (e.g., gate contact 140), the vertically stacked sidewall having a first spacer (e.g., bottom gate spacer 160) and a second spacer (e.g., top gate spacer 162), the second spacer (e.g., top gate spacer 162) being stacked on the first spacer, where the high-k material is on an inner sidewall of the second spacer (e.g., top gate spacer 162). For example, the liner of high-k dielectric material 164 is formed on the inner sidewall of the top gate spacer 162.

Further, another inner sidewall of the first spacer (e.g., bottom gate spacer 160) is free of the high-k material (e.g., high-k dielectric material 164). The common work function metal 166 is formed on the high-k material (e.g., high-k dielectric material 164) on the inner sidewall of the second spacer (e.g., top gate spacer 162) and is formed on another inner sidewall of the first spacer (e.g., bottom gate spacer 160).

The stacked complementary transistors are separated by a middle dielectric isolation layer 112. The first spacer (e.g., bottom gate spacer 160) extends above a bottom surface of a middle dielectric isolation layer 112.

The (bottom surface of) second spacer (e.g., top gate spacer 162) is above a bottom surface of a middle dielectric isolation layer 112. The stacked complementary transistors are separated by a middle dielectric isolation layer 112, the middle dielectric isolation layer 112 and the first spacer (e.g., bottom gate spacer 160) having a same material.

The stacked complementary transistors include a first transistor (e.g., bottom transistor 130) and a second transistor (e.g., top transistor 132), and the high-k material surrounding the second transistor (e.g., top transistor 132) includes a higher amount/level of oxygen (e.g., higher/greater amount of oxygen atoms) than the high-k material surrounding the first transistor (e.g., bottom transistor 130). A threshold voltage of the second transistor (e.g., top transistor 132) is different from a threshold voltage of the first transistor (e.g., bottom transistor 130), although they are formed of the same materials. The higher amount/level of the oxygen surrounding the second transistor (e.g., top transistor 132) is relative to an oxygen vacancy in the high-k material on the inner sidewall of the second spacer (e.g., top gate spacer 162), because oxygen atoms are removed from the liner of high-k dielectric material 164 on the top gate spacer 162 and transferred to the high-k dielectric material 164 surrounding the top transistor 132. An oxygen vacancy is lower in the high-k material (e.g., high-k dielectric material 164) of the second transistor than the high-k material (e.g., high-k dielectric material 164) of the first transistor.

Gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

In one or more embodiments, the ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device comprising:
stacked complementary transistors comprising a high-k material, a common work function metal, and a gate conductor metal; and
a vertically stacked sidewall adjacent to the gate conductor metal, the vertically stacked sidewall comprising a first spacer and a second spacer, the second spacer being stacked on the first spacer;
wherein the high-k material is on an inner sidewall of the second spacer.

2. The semiconductor device of claim 1, wherein an another inner sidewall of the first spacer is free of the high-k material.

3. The semiconductor device of claim 1, wherein the common work function metal is formed on the high-k material on the inner sidewall of the second spacer and is formed on an another inner sidewall of the first spacer.

4. The semiconductor device of claim 1, wherein the stacked complementary transistors are separated by a middle dielectric isolation layer.

5. The semiconductor device of claim 1, wherein the first spacer extends above a bottom surface of a middle dielectric isolation layer.

6. The semiconductor device of claim 1, wherein the second spacer is above a bottom surface of a middle dielectric isolation layer.

7. The semiconductor device of claim 1, wherein the stacked complementary transistors are separated by a middle dielectric isolation layer, the middle dielectric isolation layer and the first spacer comprising a same material.

8. The semiconductor device of claim 1, wherein:
the stacked complementary transistors comprise a first transistor and a second transistor; and
the high-k material surrounding the second transistor comprises a higher amount of oxygen than the high-k material surrounding the first transistor.

9. The semiconductor device of claim 8, wherein a threshold voltage of the second transistor is different from a threshold voltage of the first transistor.

10. The semiconductor device of claim 8, wherein the higher amount of the oxygen in the high-k material surrounding the second transistor is relative to an oxygen vacancy in the high-k material on the inner sidewall of the second spacer.

11. The semiconductor device of claim 8, wherein:
the first transistor and the second transistor comprise the high-k material; and
an oxygen vacancy in the high-k material of the second transistor is lower than the high-k material of the first transistor.

12. A method comprising:
forming stacked complementary transistors comprising a high-k material, a common work function metal, and a gate conductor metal; and
providing a vertically stacked sidewall adjacent to the gate conductor metal, the vertically stacked sidewall comprising a first spacer and a second spacer, the second spacer being stacked on the first spacer;
wherein the high-k material is on an inner sidewall of the second spacer.

13. The method of claim 12, wherein an another inner sidewall of the first spacer is free of the high-k material.

14. The method of claim 12, wherein the common work function metal is formed on the high-k material on the inner sidewall of the second spacer and is formed on an another inner sidewall of the first spacer.

15. The method of claim 12, wherein the stacked complementary transistors are separated by a middle dielectric isolation layer.

16. The method of claim 12, wherein the first spacer extends above a bottom surface of a middle dielectric isolation layer.

17. The method of claim 12, wherein the second spacer is above a bottom surface of a middle dielectric isolation layer.

18. The method of claim 12, wherein the stacked complementary transistors are separated by a middle dielectric isolation layer, the middle dielectric isolation layer and the first spacer comprising a same material.

19. The method of claim 12, wherein:
the stacked complementary transistors comprise a first transistor and a second transistor; and
the high-k material surrounding the second transistor comprises a higher amount of oxygen than the high-k material surrounding the first transistor.

20. The method of claim 19, wherein:
a threshold voltage of the second transistor is different from a threshold voltage of the first transistor, wherein the first transistor and the second transistor comprise the high-k material; and
an oxygen vacancy in the high-k material of the second transistor is lower than the high-k material of the first transistor.
